(19) United States
(12) Patent Application Publication
(10) Pub. No.: US 2009/0244859 A1
(43) Pub. Date: Oct. 1, 2009

(54) FLEXIBLE PRINTED CIRCUIT BOARD AND ELECTRONIC APPARATUS

(75) Inventors: Kiyomi MURO, Hachioji-shi (JP); Sadahiro Tamai, Ome-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/345,069

(22) Filed: Dec. 29, 2008

(30) Foreign Application Priority Data
Mar. 26, 2008 (JP) 2008-081015

(51) Int. Cl. H05K 1/00

(52) U.S. Cl. 361/749; 174/254

(57) ABSTRACT

According to one embodiment, a plurality of bumps are formed by repeatedly applying conductive paste to the conductive pattern portion, a plurality of bump-guiding openings are provided in the cover layer to align with the plurality of bumps, a plurality of crushed portions are formed by crushing heads of the plurality of bumps protruding from the cover layer through the bump-guiding openings, and a ground layer is formed on the cover layer. The ground layer is electrically connected to the plurality of crushed portions.

### CROSS-REFERENCE TO RELATED APPLICATIONS

This application is based upon and claims the benefit of priority from Japanese Patent Application No. 2008-081015, filed Mar. 26, 2008, the entire contents of which are incorporated herein by reference.

### BACKGROUND

1. Field

One embodiment of the invention relates to a flexible printed circuit board configured to transmit high-frequency signals, and to an electronic apparatus.

2. Description of the Related Art

Flexible printed circuit boards are often used for information processing apparatuses; the flexible printed circuit board can be mounted in a housing of the information processing apparatus in a bent condition, and offers a high degree of configurability. With the increased processing speed of the information processing apparatus and the increased density of circuits in the apparatus, even for the flexible printed circuit board, mounted in the housing of the apparatus, there has been a demand for a transmission line forming technique using printed circuitry for high-frequency-band signals with a transmission loss taken into account, in view of a change from a microwave (UHF) band to a centimeter wave (SHF) band, and further from the centimeter wave band to a millimeter wave (EHF) band.

For circuits with lower signal transmission rates, single end transmission lines are often used. In order to transmit signals in a high-frequency band of at least several hundred MHz, transmission lines are often used through which signals are transmitted based on a combination of the reduced voltage of the signal and a differential transmission scheme.

A conventional flexible printed circuit board with a transmission line based on the differential transmission scheme comprises a ground (GND) layer coated with a conductive paste (for example, a silver paste) so as to form a differential transmission line with a specified rated impedance.

On the flexible printed circuit board which comprises a ground layer formed using conductive paste, a conducting means should be provided to connect electrically the ground layer to the ground pattern portion (ground lines) formed on the signal layer. The conducting means is constituted by conductive junctions (conductive parts) that have been made by first making round openings in the cover layer covering the ground lines at arranged at regular intervals, each exposing the ground pattern layer, and then by applying and filling conductive paste in the round openings thus made.

The conductive junctions have been formed by applying the conductive paste by printing to the cover layer, filling the openings with the conductive paste. Inevitably, voids may be formed in the cover layer or the paste may overflow the openings made in the cover layer. To avoid this from happening, openings as large as 0.8 to 1 mm must be made in the cover layer, each exposing a ground line. The ground lines therefore need to have a width of about 2 mm (pad diameter), each at that part where a conductive junction will be formed. Consequently, traces cannot be formed in such large numbers as desired, in the limited area. Hence, a pattern of such a high density as expected can hardly be provided.

Techniques of forming conductive junctions are known, as disclosed in, for example, Jpn. Pat. Appln. KOKAI Publication No. 2005-109101. The technique discloses making openings for conduction in an insulating layer, forming conductive metal pillars in the openings for conduction, and electrically connecting a conductive shielding layer to a ground circuit.

However, the conventional techniques, wherein a ground layer is formed, can hardly achieve a high-density pattern. This is because openings as large as about 1 mm must be made in order to form the conductive junctions by applying conductive paste.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary sectional side view showing a configuration of an essential part of a flexible printed circuit board according to a first embodiment of the invention;

FIG. 2 is an exemplary plan view showing the configuration of an essential part of the flexible printed circuit board according to the first embodiment of the invention;

FIG. 3 is an exemplary enlarged plan view showing a part of the flexible printed circuit board shown in FIG. 2;

FIG. 4 is an exemplary sectional side view showing Step A of manufacturing the flexible printed circuit board according to the first embodiment of the invention;

FIG. 5 is an exemplary sectional side view showing Step B of manufacturing the flexible printed circuit board according to the first embodiment of the invention;

FIG. 6 is an exemplary sectional side view showing Step C of manufacturing the flexible printed circuit board according to the first embodiment of the invention;

FIG. 7 is an exemplary sectional side view showing Step D of manufacturing the flexible printed circuit board according to the first embodiment of the invention;

FIG. 8 is an exemplary sectional side view showing Step E of manufacturing the flexible printed circuit board according to the first embodiment of the invention;

FIG. 9 is an exemplary sectional side view showing Step F of manufacturing the flexible printed circuit board according to the first embodiment of the invention;

FIG. 10 is an exemplary sectional side view showing Step G of manufacturing the flexible printed circuit board according to the first embodiment of the invention;

FIG. 11 is an exemplary sectional side view showing Step H of manufacturing the flexible printed circuit board according to the first embodiment of the invention;

FIG. 12 is an exemplary sectional side view showing another configuration of the flexible printed circuit board according to the first embodiment of the invention;

FIG. 13 is an exemplary diagram explaining the configuration of a shielding film used in the flexible printed circuit board shown in FIG. 12;

FIG. 14 is an exemplary sectional side view showing a step of manufacturing the flexible printed circuit board shown in FIG. 12;

FIG. 15 is an exemplary sectional side view showing another step of manufacturing the flexible printed circuit board shown in FIG. 12;

FIG. 16 is an exemplary sectional side view showing still another step of manufacturing the flexible printed circuit board shown in FIG. 12;

FIG. 17 is an exemplary sectional side view showing a further step of manufacturing the flexible printed circuit board shown in FIG. 12;

FIG. 18 is an exemplary perspective view showing an outer appearance of a portable computer according to a second embodiment of the invention;

FIG. 19 is an exemplary perspective view showing a main body of the portable computer according to the second embodiment of the invention with the keyboard removed from the main body;

FIG. 20 is an exemplary perspective view of a hard disk drive incorporated in the portable computer according to the second embodiment of the invention and the case holding the hard disk drive, as viewed obliquely from below;

FIG. 21 is an exemplary perspective view of the hard disk drive and the case supporting the hard disk drive, which are provided in the portable computer according to the second embodiment of the invention, as viewed obliquely from above;

FIG. 22 is an exemplary side view illustrating how the flexible printed circuit board is arranged in the portable computer according to the second embodiment of the invention; and

FIG. 23 is an exemplary perspective view showing a part of the main body of the portable computer according to the second embodiment of the invention, with the keyboard, hard disk drive and case removed from the main body.

### DETAILED DESCRIPTION

Various embodiments according to the invention will be described hereinafter with reference to the accompanying drawings. In general, according to one embodiment of the invention, there is provided a flexible printed circuit board, comprising: a base layer, a signal layer formed on the base layer, a cover layer covering the signal layer, a conductive pattern portion provided in the signal layer, a plurality of bumps formed by repeatedly applying conductive paste to the conductive pattern portion, a plurality of bump-guiding openings provided in the cover layer to align with the plurality of bumps, a plurality of crushed portions formed by crushing heads of the plurality of bumps protruding from the cover layer through the bump-guiding openings, and a ground layer formed on the cover layer, the ground layer being electrically connected to the plurality of crushed portions.

### First Embodiment

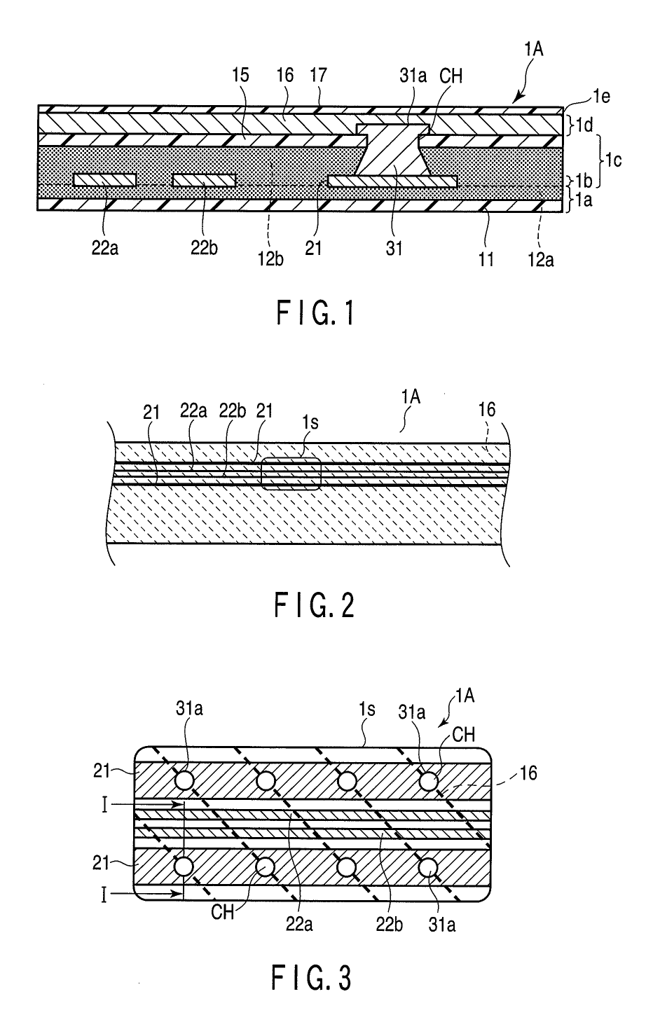

FIG. 1 is a sectional side view showing an essential part of a flexible printed circuit board according to a first embodiment of the invention. FIG. 2 is a plan view showing the configuration of the flexible printed circuit board. FIG. 3 is an enlarged plan view showing a part of the flexible printed circuit board shown in FIG. 2. The sectional side view of FIG. 1 is taken along line I-I shown in FIG. 3. FIG. 3 is an enlarged view of the part 1s of the configuration shown in FIG. 2.

As shown in FIG. 1, the flexible printed circuit board 1A according to the first embodiment comprises a base layer 1a, a signal layer 1b formed on the base layer 1a, a cover layer 1c covering the signal layer 1b, a ground layer 1d formed on the cover layer 1c, and a protective layer 1e formed on the ground layer 1d.

The base layer la comprises a base-layer polyimide 11 and a base-layer adhesive 12a. The base layer 1a is an insulating base on which the signal layer 1b is formed.

The signal layer 1b comprises the ground lines 21 and the signal transmission lines 22a and 22b forming conductive patterns made of copper foil, as shown in FIG. 2. The signal transmission lines 22a and 22b form signal transmission paths based on a differential transmission scheme (i.e., differential-signal transmission paths).

A plurality of solid bumps 31, each of which is shaped in form of a cone, are provided on the ground lines 21 and spaced apart at prescribed intervals, as shown in FIG. 3. The bumps 31 have been formed by repeatedly applying conductive paste. The ground lines 21 have a trace width of about 0.2 to 0.3 mm. The bumps 31 on the ground lines 21 have a diameter of about 0.15 to 0.20 mm.

The cover layer 1c comprises a cover-layer polyimide 15 and a cover-layer adhesive 12b. The cover-layer adhesive 12b covers the signal layer 1b and sticks to the base-layer adhesive 12a. The cover layer 1c has spot-shaped bump-guiding openings CH aligned with the bumps 31 formed on the ground lines 21.

Each bump 31 comprises a circular flange-shaped crushed portion 31a that is formed by crushing flatly the head of the bump 31 protruding from the cover layer 1c though a bump-guiding opening CH. The crushed portion 31a achieves the electrical connection of the bump 31 and ground layer 1d.

The ground layer 1d comprises a metal film 16. The ground layer 1d is formed by applying, for example, conductive paste on the upper surface of the cover layer 1c. In this embodiment, the ground layer 1d is formed by applying silver paste on the cover layer 1c and on the crushed portions 31a of the bumps 31, which protrude from the cover layer 1c.

The protective layer 1e comprises an overcoat 17. The protective layer 1e covers the upper surface and sides of the ground layer 1d.

As described above, conductive paste is repeatedly applied, forming the bumps 31 at prescribed intervals on the ground lines 21, bump-guiding openings CH are made in the cover layer 1c, in alignment with the bumps 31, the heads of the respective bumps 31 are crushed flatly, forming the crushed portions 31a, so that the crushed portions 31a are electrically connected to the ground layer 1d. The bumps 31 have a small diameter of about 0.15 to 0.20 mm. This ensures the electrical connection of the ground lines 21 to the ground layer 1d. The ground lines 21 can have a small width of about 0.2 to 0.3 mm. The signal transmission lines 22a and 22b can therefore be arranged at high density in the signal layer 1b.

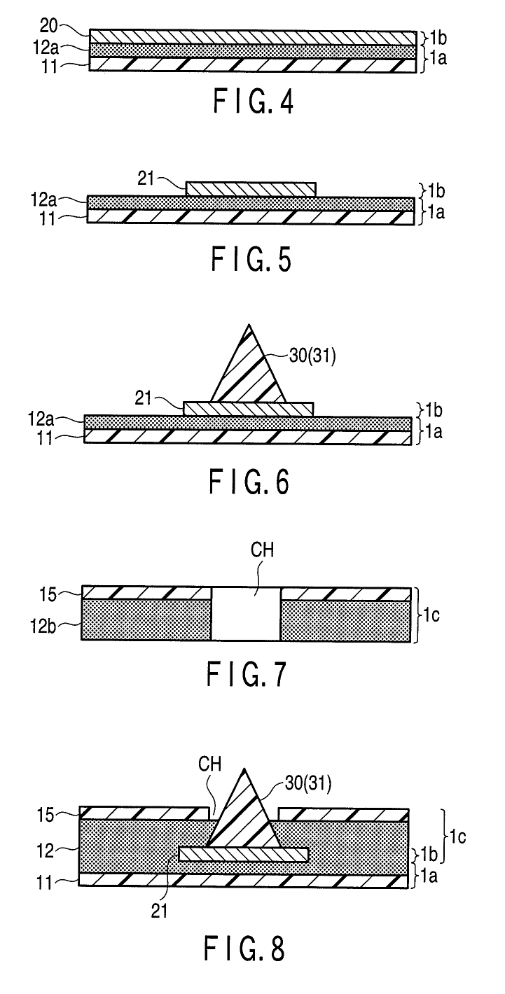

A method of manufacturing the flexible printed circuit board 1A will be explained, with reference to FIGS. 4 to 11 each showing a manufacturing step, and also with reference to FIGS. 1 to 3.

In Step A shown in FIG. 4, a substrate is prepared for the flexible printed circuit board 1A. Specifically, there is provided an FPC base that is formed by adhering a copper foil 20 for the signal layer 1b to the base-layer polyimide 11 of the base layer 1a with the base-layer adhesive 12a.

In Step B shown in FIG. 5, a trace pattern of the ground lines 21 for the signal layer 1b is formed on the base layer 1a. Specifically, the ground lines 21 and the signal transmission lines 22a and 22b (differential-signal transmission paths) are formed, for example, by etching the copper foil 20. In practice, a number of signal transmission lines are formed and arranged. The ground lines 21 have a width of about 0.2 to 0.3 mm.

In Step C shown in FIG. 6, cone-shaped bumps 30 for the solid bumps 31 are formed, in a pattern layout designed, on the ground lines 21 of the signal layer 1b. Specifically, silver paste is applied several times (for example, about three times) by means of screen printing. Each silver paste coating is dried before the next coating is formed on it. As a result, bumps 30, each shaped in form of a cone, are formed.

In Step D shown in FIG. 7, the cover-layer adhesive 12b and the cover-layer polyimide 15 for the cover layer 1c are formed, and bump-guiding openings CH are provided in the cover-layer adhesive 12b and the cover-layer polyimide 15 of the cover layer 1c to align with the cone-shaped bumps 30 formed on the ground lines 21. Specifically, the bump-guiding openings CH are provided by cutting part of the cover-layer adhesive 12b and the cover-layer polyimide 15 with laser beam, drilling, or the like, so as to guide the cone-shaped bumps 30.

In Step E shown in FIG. 8, the cover layer 1c is provisionally press-bonded to the base layer 1a so that the base-layer adhesive 12a and the cover-layer adhesive 12b are bonded together, forming an adhesive layer 12 for the signal layer 1b interposed between the base-layer polyimide 11 and the cover-layer polyimide 15. The cone-shaped bumps 30 provided on the ground lines 21 pass through the bump-guiding openings CH provided in the cover layer 1c, and have their heads exposed protruding from the bump-guiding openings CH.

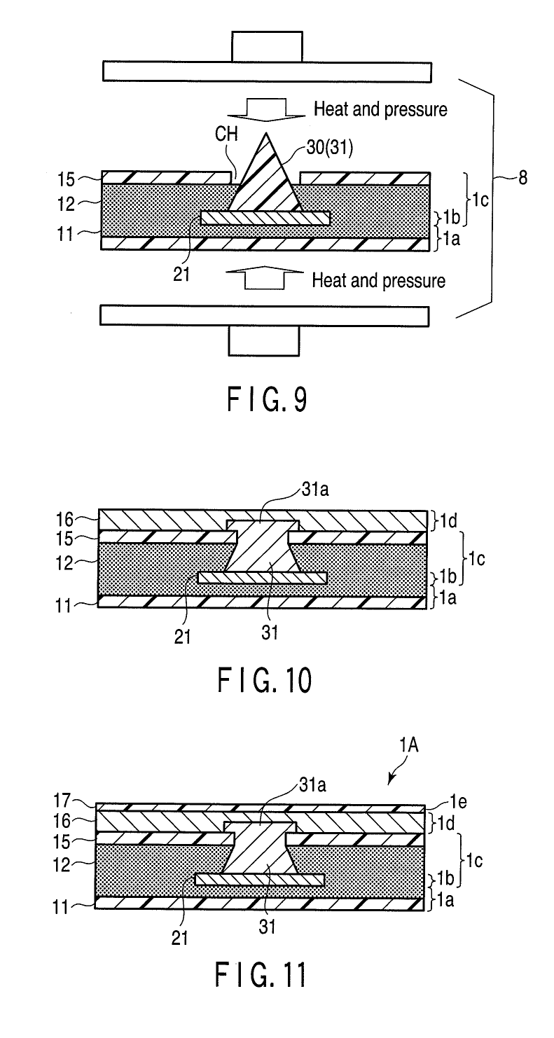

In Step F shown in FIG. 9, a press 8 hot-presses the base layer 1a and the cover layer 1c, which have been provisionally press-bonded together in Step E. The heads of the cone-shaped bumps 30, which protrude from the bump-guiding openings CH, are crushed flatly, and thus crushed portions 31a are formed on part of the cover-layer polyimide 15. The base layer 1a and the cover layer 1c, thus hot-pressed by the press 8, are bonded together, forming the solid bumps 31 which has certain hardness and part of which is exposed on the cover layer 1c.

In Step G shown in FIG. 10, silver paste is applied, as shielding material, to the cover layer 1c provided with the crushed portions 31a of the solid bumps 31 to form a ground layer 1d comprising the metal film 16 on the cover layer 1c. Each crushed portion 31a is thus coated with silver paste in its entirety. Therefore, the metal film 16 of the ground layer 1d is reliably electrically connected to the ground lines 21 by the bumps 31, each having a small diameter.

In Step H shown in FIG. 11, a protective layer 1e comprising the overcoat 17 is formed on the upper surface and sides of the ground layer 1d.

According to the above-described method of manufacturing the flexible printed circuit board 1A, conductive paste is repeatedly applied, forming the bumps 31 at prescribed intervals on the ground lines 21, bump-guiding openings CH are made in the cover layer 1c, in alignment with the bumps 31, the heads of the respective bumps 31 are crushed flatly, forming the crushed portions 31a, so that the crushed portions 31a are electrically connected to the ground layer 1d. Thus, it is possible to realize the bumps 31 having a small diameter (about 0.15 to 0.20 mm), ensuring the electrical connection of the ground lines 21 to the ground layer 1d.

Consequently, it is possible to realize the flexible printed circuit board 1A, in which the ground lines 21 can be thin, increasing the density at which lines are arranged in the signal layer 1b.

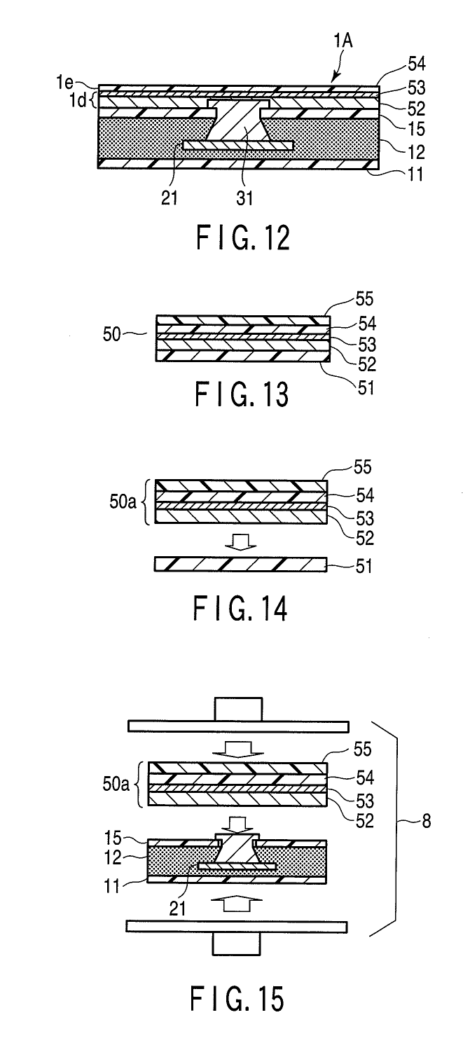

In the first embodiment described above, the metal film 16 of the ground layer 1d is formed by applying electrically conductive paste (silver paste), and the overcoat 17 of the protective layer 1e is formed to cover the upper surface and sides of the ground layer 1d. Instead, a shielding film may be applied to form the ground layer 1d comprising a conductive adhesive 52 and a metal foil 53, and the protective layer 1e comprising an insulating film (overcoat) 54, as shown in FIG. 12. In the flexible printed circuit board 1A shown in FIG. 12, a conductive adhesive 52 and a metal foil 53 constitute the ground layer 1d serving as an electromagnetic shielding layer. FIG. 13 shows the structure of the shielding film used in the flexible printed circuit board shown in FIG. 12. FIGS. 14 to 17 show the steps of forming the ground layer used in the flexible printed circuit board of FIG. 12.

The shielding film 50 shown in FIG. 13 comprises a removal film 51, a conductive adhesive layer 52, a metal foil 53, an insulating film 54, and a reinforcing film 55.

In the step shown in FIG. 14, the removable film 51 of the shielding film 50 shown in FIG. 13 is peeled off to remain a shielding film 50a.

In the step shown in FIG. 15, the shielding film 50a is hot-pressed by a press 8 to a cover layer 1c of the type shown in FIG. 9, with the conductive adhesive layer 52 set in contact with the cover layer 1c and exposed now because of the removal of the film 51. Thus, the shielding film 50a is heated and pressed to the member formed in Step F shown in FIG. 9 (i.e., member comprising the base layer 1a and the cover layer 1c and also comprising silver bumps 31 on the ground lines 21 with a crushed portion 31a exposed at the cover layer 1c). The conductive adhesive layer 52 is thereby bonded to the entire surface of each crushed portion 31a. This achieves reliable electrical connection of the ground layer 1d comprising the conductive adhesive layer 52 and the metal foil 53 with the ground lines 21.

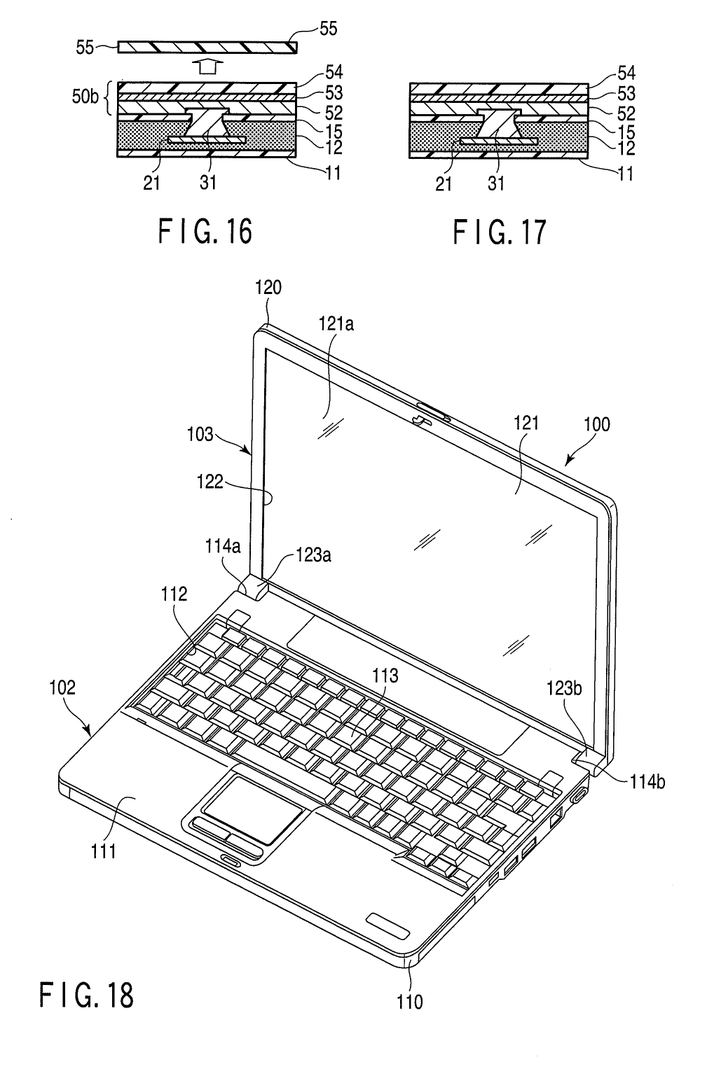

Next, in the step shown in FIG. 16, the reinforcing film 55 is peeled from the shielding film 50a to remain a shielding film 50b. As a result, a flexible printed circuit board shown in FIG. 17 is manufactured, which has a ground layer 1d comprising the conductive adhesive layer 52 and the metal foil 53.

As indicated above, according to the first embodiment of the invention, the ground layer 1d is formed using the conductive paste or shielding film, in flexible printed circuit board. Each opening achieving the electrical connection therefore has a small diameter, which increases the density of the trace pattern can therefore be high.

### Second Embodiment

FIGS. 18 to 23 show a configuration of an electronic apparatus according to a second embodiment of the invention comprising, as a component, the flexible printed circuit board 1A according to the first embodiment of the invention, described above.

The electronic apparatus shown in FIGS. 18 to 23 implements a portable computer that transmits signals between a motherboard and hard disk drive (HDD) based on the Serial ATA-2 (SATA-2), using the flexible printed circuit board 1A, shown in FIGS. 1 to 11.

FIG. 18 shows the notebook-type portable computer 100. The portable computer 100 comprises a main body 102 and a display unit 103.

As shown in FIG. 18, the main body 102 comprises a first housing 110 that can be installed on a desk. The first housing 110 is shaped in form of a flat box and comprises a palm rest 111 and a keyboard mounting portion 112 on a top surface portion of the first housing 110. The palm rest 111 extends, in a front half of the first housing 110, along a width direction of the first housing 110. The keyboard mounting portion 112 is positioned behind the palm rest 111. A keyboard 113 is mounted in the keyboard mounting portion 112.

The first housing 110 comprises a pair of display support portions 114a and 114b located in the rear of the first housing 110 and separated from each other in the width direction.

The display unit 103 comprises a second housing 120 and for example, a liquid crystal display device 121 as a display device. The second housing 120 is formed in form of a flat box, and a display screen 121a of the liquid crystal display device 121 is exposed in a display opening 122.

The second housing 120 comprises a pair of leg portions 123a and 123b. The leg portions 123a and 123b are pivotally movably supported in the display support portions 114a and 114b of the first housing 110 via hinges (not shown). This pivotally moving mechanism allows the display unit 103 to move pivotally between a closed position where the display unit 103 covers the palm rest 111 and the keyboard 113 from above and an open position where the display unit 103 is raised upright to expose the palm rest 111 and keyboard 113.

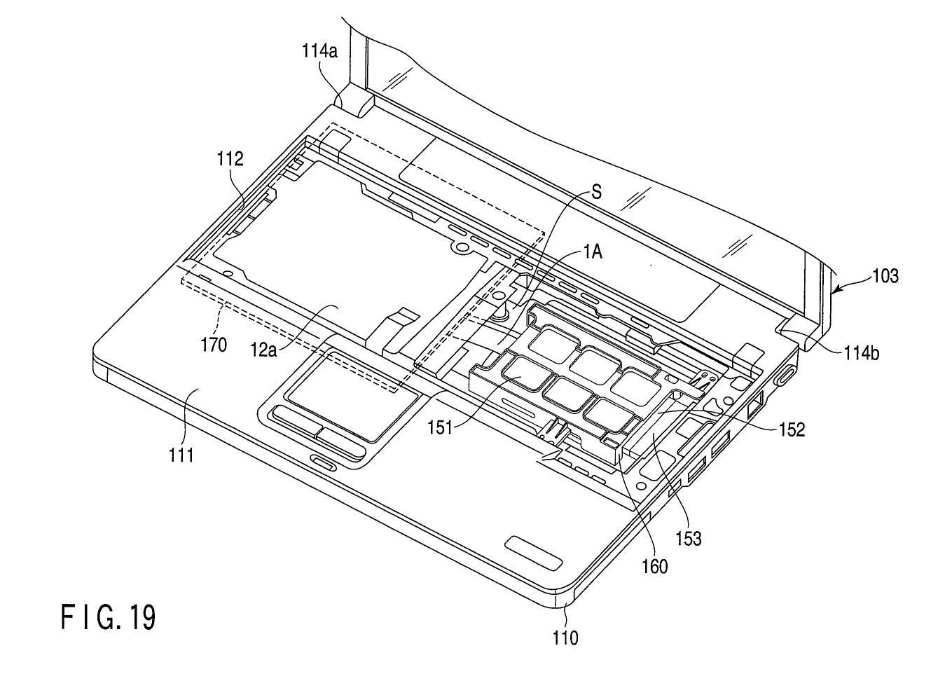

As shown in FIGS. 19, 22, and 23, a space S is formed in the keyboard mounting portion 112 of the main body 102 below a mounting position of the keyboard 113 so that a hard disk drive 151 and a motherboard 170 are accommodated in the space S in juxtaposition.

The motherboard 170 and the hard disk drive 151 are mounted in the space S in the main body 102. The hard disk drive 151 and the motherboard 170 perform data read and write accesses via transmission lines for differential signals at a communication speed conforming to the Serial ATA-2.

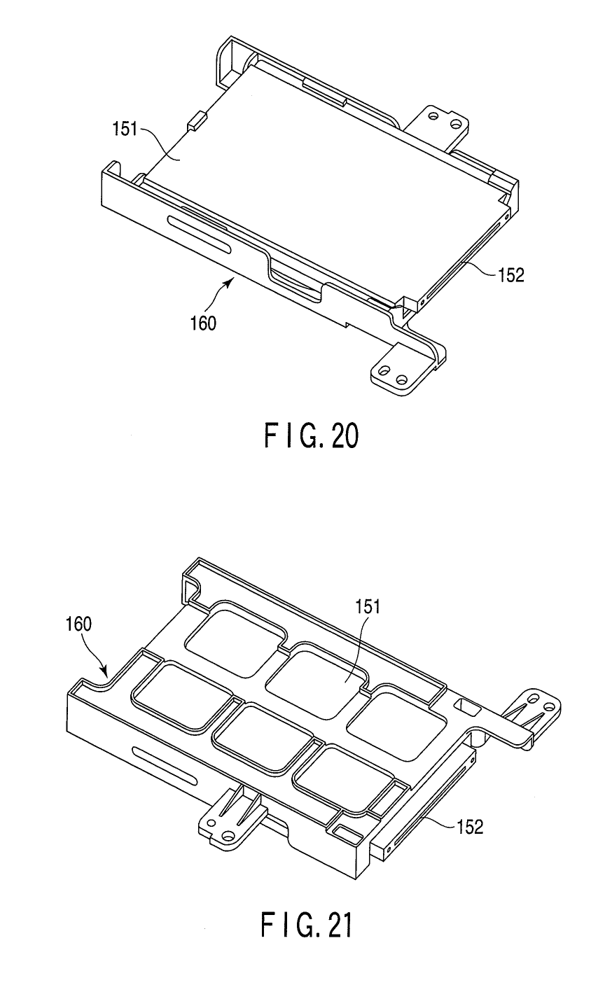

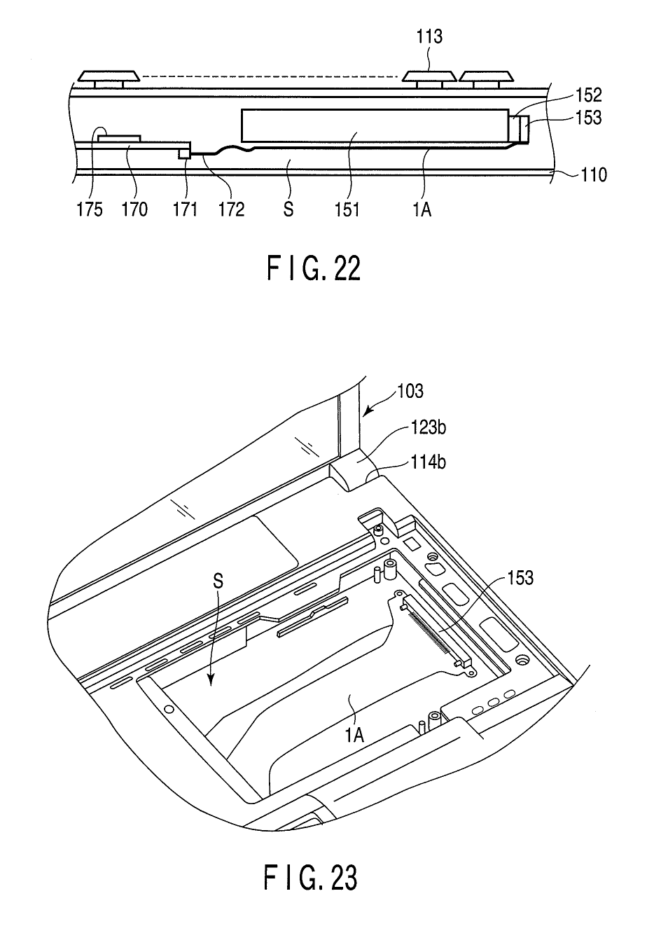

As shown in FIGS. 20 and 21, the hard disk drive 151 held in the case 160 is mounted in the space S in the main body 102 by a fastening mechanism (not shown). In FIG. 22, the case 160, which supports the hard disk drive 151, is omitted. The motherboard 170 is mounted in the space in the main body 102 in juxtaposition with the hard disk drive 151 by means of a fastening mechanism (not shown).

A CPU controlling the system and a peripheral circuit for the CPU are mounted on the motherboard 170. For example, a south bridge IC 175 mounted in the peripheral circuit for the CPU; the south bridge IC 175 makes up an I/O hub to which the hard disk drive 151 is connected so as to form a circuit. A connecter 170 (which comprises, for example, a crimping terminal of a lead insertion type) is mounted on the motherboard 170; the connecter 170 connects the hard disk drive 151 to the south bridge IC 175 so as to form a circuit.

The hard disk drive 151 comprises a connector (in this example, a connector receptacle) 152 making up an external connection interface mechanism.

The connector (connector receptacle) 152 of the hard disk drive 151 is connected to the connector (which comprises the crimping terminal of the lead insertion type) 171, mounted on the motherboard 170, via the flexible printed circuit board 1A shown in FIGS. 1 to 11 so as to form a circuit.

In the second embodiment, the flexible printed circuit board 1A connects an external connection interface of the hard disk drive 151 to an I/O connection interface of the motherboard 170 as transmission ends of information processing elements so as to form a circuit. The external connection interface of the hard disk drive 151 is the connector (connector receptacle) 152. The I/O connection interface of the motherboard 170 is the connector (which comprises the crimping terminal of the lead insertion type) 171, connected to the south bridge IC 175 so as to form a circuit.

The flexible printed circuit board 1A applied to the second embodiment offers a trace length from one side portion of the first housing 110 to a substantial center of the housing. The flexible printed circuit board 1A is located in the space S in the first housing 110 and between the hard disc 151 and the motherboard 170 so as to extend along a rear surface of the hard disk drive 151 and through a narrow space (a narrow gap corresponding to the entire space excluding component mounting areas) formed behind the hard disk drive 151 and serving as an installation path.

The flexible printed circuit board 1A comprises a connector (connector plug) 153 located at one end in a connection direction and coupled to a connector (connector receptacle) 152 of the hard disk drive 151. The flexible printed circuit board 1A also comprises a connecting lead terminal portion 172 located at one end in the connection direction and fittingly attached to the connector (which comprises the crimping terminal of the lead insertion type) 171, mounted on the motherboard 170.

The flexible printed circuit board 1A is installed in the installation path so that the connector (connector receptacle) 153, provided at one end of the flexible printed circuit board 1A in the connection direction, is coupled to the connector (connector receptacle) 152 of the hard disk drive 151 and so that the connecting lead terminal 172, provided at the other end of the flexible printed circuit board 1A in the connection direction, is fittingly attached (pressure bonded) to the connector (which comprises the crimping terminal of the lead insertion type) 171, mounted on the motherboard 170.

High-speed transmission of read and write data complying with the Serial ATA-2 specifications is performed between the hard disk drive 151 and the south bridge IC 175, mounted on the motherboard 170, via the flexible printed circuit board 1A.

This flexible printed circuit board 1A comprises the base layer 1a, the signal layer 1b formed on the base layer 1a, the cover layer 1c covering the signal layer 1b, the ground layer 1d formed on the cover layer 1c, and the protective layer 1e, as shown in FIG. 1. The signal layer 1b comprises the ground lines 21 and the signal transmission lines 22a and 22b forming conductive patterns made of copper foil, as shown in FIG. 2. The plurality of solid bumps 31, each of which is shaped in form of a cone, are provided on the ground lines 21 and spaced apart at prescribed intervals, as shown in FIG. 3. Each bump 31 comprises the circular flange-shaped crushed portion 31a that is formed by crushing flatly the head of the bump 31 protruding from the cover layer 1c though the bump-guiding opening CH.

As described above, conductive paste is repeatedly applied, forming the bumps 31 at prescribed intervals on the ground lines 21, bump-guiding openings CH are made in the cover layer 1c, in alignment with the bumps 31, the heads of the respective bumps 31 are crushed flatly, forming the crushed portions 31a, so that the crushed portions 31a are electrically connected to the ground layer 1d. The bumps 31 have a small diameter. This ensures the electrical connection of the ground lines 21 to the ground layer 1d. The ground lines 21 can have a small width. The signal transmission lines 22a and 22b can therefore be arranged at high density in the signal layer 1b. This contributes to reducing the size and weight of the apparatus.

As has been described, the embodiments of the invention can allow the trace-pattern elements to be arranged at high density in a flexible printed circuit board which has a ground layer formed using conductive paste or shielding film.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A flexible printed circuit board, comprising:
a base layer;
a signal layer formed on the base layer;
a cover layer covering the signal layer;
a conductive pattern portion in the signal layer;
a plurality of bumps formed by applying conductive paste to the conductive pattern portion;
a plurality of bump-guiding openings in the cover layer to align with the plurality of bumps;
a plurality of crushed portions formed by crushing heads of the plurality of bumps protruding from the cover layer through the bump-guiding openings; and
a ground layer formed on the cover layer, the ground layer configured to be electrically connected to the plurality of crushed portions.

2. The flexible printed circuit board of claim 1, wherein the plurality of bumps on the conductive pattern portion have a diameter of at most 0.2 mm.

3. The flexible printed circuit board of claim 1, wherein the plurality of bumps are silver bumps formed by printing silver paste to the conductive pattern portion a plurality of times.

4. The flexible printed circuit board of claim 1, wherein the plurality of crushed portion is formed of circular flanges on the cover layer, closing the plurality of bump-guiding openings.

5. The flexible printed circuit board of claim 1, wherein the ground layer is configured to serve as an electromagnetic shield to a signal transmission path formed in the signal layer and electrically connected by the bump to the conductive pattern portion.

6. The flexible printed circuit board of claim 5, wherein the conductive pattern portion is a ground line comprising a current path for a direct-current source, and the signal transmission path is a differential-signal path extending along the ground line.

7. The flexible printed circuit board of claim 5, wherein the ground layer is formed by applying silver paste to the cover layer.

8. The flexible printed circuit board of claim 5, wherein the ground layer is formed by a metal foil adhered to the cover layer with conductive adhesive.

9. An electronic apparatus comprising:
a body;
a plurality of data-processors in the body comprising high-frequency signal transmission terminals; and
a flexible printed circuit board comprising signal transmission lines between the signal transmission terminals of the data-processors,
the flexible printed circuit board comprising:
a base layer;
a signal layer formed on the base layer;
a cover layer covering the signal layer;
a conductive pattern portion in the signal layer;
a plurality of bumps formed by applying conductive paste to the conductive pattern portion;
a plurality of bump-guiding openings in the cover layer configured to align with the plurality of bumps;
a plurality of crushed portions formed by crushing heads of the plurality of bumps protruding from the cover layer through the bump-guiding openings; and
an electromagnetic shielding layer formed on the cover layer, the electromagnetic shielding layer configured to be electrically connected to the plurality of crushed portions.

10. The electronic apparatus of claim 9, wherein the data-processors are circuit components configured to transmit high-frequency signals at high speed complying with SATA-2 specification.
